(19) United States
(12) Patent Application Publication
(10) Pub. No.: US 2024/0128994 A1
(43) Pub. Date: Apr. 18, 2024

(54) TRANSMISSION SYSTEM

(71) Applicant: Molex, LLC, Lisle, IL (US)

(72) Inventors: Nobumasa Motohashi, Yamato (JP); Akihiro Shimotsu, Yamato (JP); Shuji Somekawa, Yamato (JP); Hiroyuki Yajima, Yamato (JP)

(21) Appl. No.: 18/285,654

(22) PCT Filed: Jun. 29, 2021
(86) PCT No.: PCT/JP2021/024600

§ 371 Date: Oct. 5, 2023

(51) Int. Cl. H04B 1/40; H01P 3/16; H01Q 1/24; H01Q 1/38; H05K 1/02

(52) U.S. Cl. CPC H04B 1/40; H01P 3/16; H01Q 1/243; H01Q 1/38; H05K 1/0243; H05K 2201/10098

(57) ABSTRACT

An electronic device that suppresses the number of signal wires and suppresses attenuation of signal in a transmission path is provided. The electronic device includes an antenna provided on a first circuit board, an antenna provided on a second circuit board, and a dielectric waveguide provided between the antenna and the antenna. In addition, the first circuit board includes a serializer and an RF circuit that modulates the serial signal output from the serializer and outputs the signal to the antenna. The second circuit board includes an RF circuit that demodulates an RF signal input from the antenna and a deserializer that converts the serial signal output from the RF circuit to a parallel signal.

### TECHNICAL FIELD

The present disclosure relates to transmission and reception of signals between circuit boards.

### BACKGROUND

The output signals of various sensors are input to a microprocessor inside an electronic device. For example, electronic devices such as a smartphone or tablet PC include an acceleration sensor, a touch sensor, an image sensor, and the like, and the output signals thereof are input to the microprocessor. If the sensors and microprocessor are not mounted on the same board, the board on which the microprocessor is mounted, and the sensor may be electrically connected via a wire such as an FPC (Flexible Printed Circuit) or an FFC (Flexible Flat Cable).

### SUMMARY

In recent years, the types of sensors installed in an electronic device have increased, and there is a problem that the number of signal wires for transmission and reception of data has increased in electronic devices. On this point, there is a method of converting the output of a plurality of sensors to a serial signal and transmitting and receiving the serial signal from a first board to a second board using a serializer. However, when attempting to transmit and receive high-speed serial signals by wire, a longer length of the signal wire and a higher frequency leads to greater signal attenuation.

A transmission system proposed by the present disclosure includes:
a first circuit board provided with a first antenna;
a second circuit board provided with a second antenna; and
a first dielectric waveguide provided between the first antenna and the second antenna. The first circuit board includes a serializer and a first RF circuit that modulates the serial signal output from the serializer and outputs the signal to the first antenna as an RF signal. The second circuit board includes a second RF circuit that demodulates an RF signal input from the second antenna and outputs the signal as a serial signal and a deserializer that converts the serial signal output from the second RF circuit and outputs the signal as a parallel signal.

The transmission system as described above, wherein
a first connector is mounted on the first circuit board,
a second connector is mounted on the second circuit board, and
the first dielectric waveguide includes a first end part provided with a connector for connecting to the first connector and a second end part provided with a connector for connecting to the second connector.

The transmission system as described above may include a first component and a second component. A conductor line may be formed on an outer surface of the first dielectric waveguide, and one of the first component and the second component may output a signal or direct current via the conductor line to another component.

The transmission system as described above, further including:
a third antenna formed on the first circuit board;
a fourth antenna formed on the second circuit board; and
a second dielectric waveguide arranged between the third antenna and the fourth antenna.

The transmission system as described above, wherein
a first RF module having the first RF circuit and the first antenna mounted therein is attached to the first circuit board, and
a second RF module having the second RF circuit and the second antenna mounted therein is attached to the second circuit board.

The transmission system as described above, wherein the first circuit board and the second circuit board are arranged facing each other in a first direction,
the first RF module and the second RF module are arranged so that the first antenna and the second antenna face each other, and
the dielectric waveguide is arranged along the first direction between the first antenna and the second antenna.

### BRIEF DESCRIPTION OF THE DRAWINGS

FIG. 1 is a diagram depicting an electronic device as an example of a transmission system proposed by the present disclosure;

FIG. 2 is a plan view depicting an example of an antenna formed on a circuit board;

FIG. 3A is a diagram depicting a modified example of an electronic device proposed in the present disclosure;

FIG. 3B is a cross section view of a dielectric waveguide of the electronic device depicted in FIG. 3A;

FIG. 4 is a diagram depicting another modified example of an electronic device proposed by the present disclosure;

FIG. 5 is a diagram depicting yet another modified example of an electronic device proposed by the present disclosure;

FIG. 6A is a diagram depicting an example of an arrangement of a circuit board, dielectric waveguide, and the like for an electronic device proposed in the present disclosure;

FIG. 6B is a diagram depicting another example of an arrangement of the circuit board, the dielectric waveguide, and the like; and

FIG. 6C is a diagram depicting yet another example of an arrangement of the circuit board, dielectric waveguide, and the like.

### DETAILED DESCRIPTION

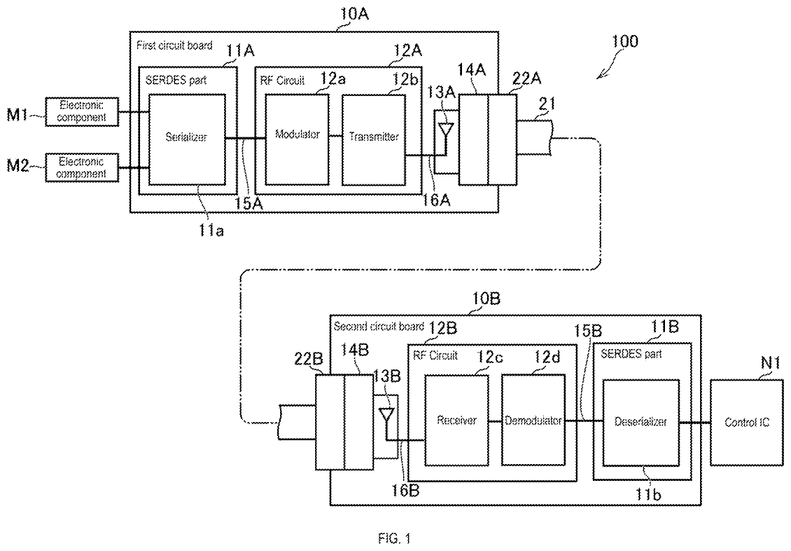

A description is provided for a transmission system proposed by the present disclosure. FIG. 1 is a diagram depicting an electronic device 100 as an example of a transmission system proposed by the present disclosure. The electronic device 100 includes a mobile terminal (for example, smartphone), a personal computer, a server device, a game device, or the like, but is not necessarily limited to these. Note that the transmission system disclosed in the present disclosure is not limited to an electronic device and may be a system composed of a sensor and circuit board mounted on an automobile, industrial machinery, a robot, or the like.

The electronic device 100 includes a first circuit board 10A and a second circuit board 10B. The circuit boards 10A and 10B are so-called rigid circuit boards such as a glass epoxy board, a composite board with paper epoxy and glass epoxy as a base material, an alumina board, or the like. The circuit boards 10A and 10B may be a Flexible Printed Circuit (FPC) composed of resin such as polyimide, polyester, or the like.

The electronic device 100 includes a dielectric waveguide 21. High frequency signals are transmitted and received between the first circuit board 10A and the second circuit board 10B via the dielectric waveguide 21. In the present specification, “high frequency” means millimeter waves (28 GHz to 300 GHz) and sub-millimeter waves (300 GHz or higher).

The first circuit board 10A may be provided with a SerDes part 11A, an RF circuit 12A, an antenna 13A, and a connector 14A. In addition, the first circuit board 10A may be provided with sensors M1 and M2. In addition, the second circuit board 10B may be provided with a SerDes part 11B, an RF circuit 12B, an antenna 13B, and a connector 14B.

The SerDes part 11A of the first circuit board 10A may have a serializer 11a. The SerDes part 11B of the second circuit board 10B may have a deserializer 11b. Digital signals are input from one or a plurality of electronic components built-into the electronic device 100 into a serializer 11a. For example, as depicted in FIG. 1, the output signals (digital signals) of the plurality of electronic components M1 and M2 are input into the serializer 11a. The electronic components M1 and M2 may be sensors, for example. Specifically, the electronic components M1 and M2 may be an acceleration sensor built-in to the electronic device 100 and a temperature sensor for detecting temperature of a battery (not depicted) built-in to the electronic device 100. The electronic components M1 and M2 may be a Wi-Fi (registered trademark) wireless communication module, a communication module for a mobile communication system (for example, a 5th generation mobile communication system), or a GNSS (Global Navigation Satellite System) receiver. An output signal of the electronic components M1 and M2 may be input to the serializer 11a via an A/D converter (not shown). The serializer 11a, for example, collects and serializes the output signals of the plurality of electronic components M1 and M2. In other words, the serializer 11a generates a series of serial signals containing the output signals of the plurality of electronic components M1 and M2. A deserializer 11b of the SerDes part 11B receives serialized output signals of the electronic components M1 and M2 via the RF circuit 12A, dielectric waveguide 21, and RF circuit 12B, and re-separates and outputs the serialized plurality of output signals.

A parallel signal may be input into the serializer 11a from one of the electronic components M1 (or M2). The serializer 11a may then convert this parallel signal into a serial signal. For example, the electronic components M1 and M2 may be a touch sensor that detects position of a user's finger on a display provided on the electronic device 100 or an image sensor (for example, a CMOS image sensor). A parallel signal may be input from various sensors to the serializer 11a, and the serializer 11a may convert these parallel signals into a serial signal. In this case, the deserializer 11b converts the serial signal received via the RF circuit 12A, the dielectric waveguide 21, and the RF circuit 12B to the original parallel signals and outputs these signals. The output of the deserializer 11b is input to other electronic components built-in to the electronic device 100. Here, electronic components that receive a signal from the deserializer 11b may be a control IC (N1) including, for example, a CPU (Central Processing Unit) or memory.

The serializer 11a may convert the number of bits of the parallel signal. For example, the serializer 11a may convert an 8-bit parallel signal to a 10-bit serial signal (in other words, 8B10B encoding processing may be executed). The deserializer 11b may execute the opposite conversion to that of the serializer 11a on a number of bits. For example, the deserializer 11b may convert 10-bit serial data to 8-bit parallel data.

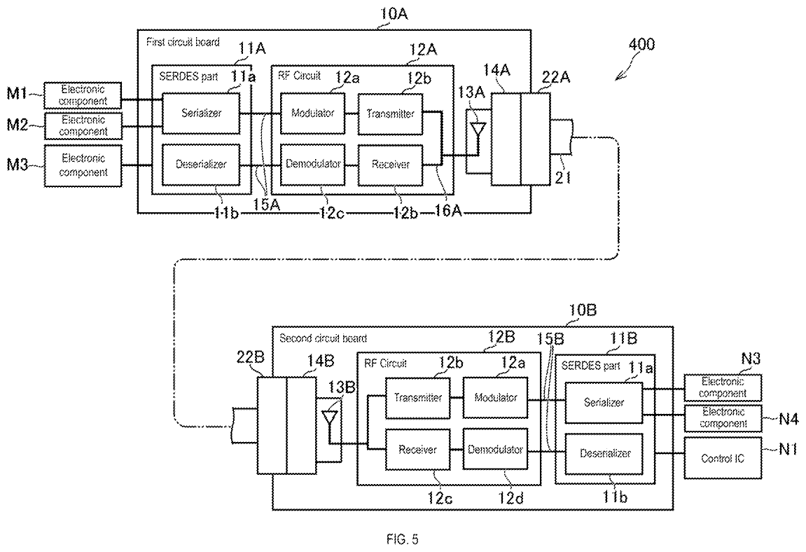

Note that the SerDes part 11A of the first circuit board 10A may have a deserializer in addition to the serializer 11a (see FIG. 5). In this case, the SerDes part 11B of the second circuit board 10B may have a serializer in addition to the deserializer 11b (see FIG. 5).

As depicted in FIG. 1, the SerDes part 11A (serializer 11a) is connected to the RF circuit 12A on the first circuit board 10A via a differential transmission line 15A formed on the first circuit board 10A. In a similar manner, the SerDes part 11B (serializer 11b) is connected to the RF circuit 12B on the second circuit board 10B via a differential transmission line 15B formed on the second circuit board 10B. The differential transmission lines 15A and 15B may be microstrip lines or strip lines.

As depicted in FIG. 1, the RF circuit 12A of the first circuit board 10A may include a modulator 12a and a transmitter 12b. In addition, the RF circuit 12B of the second circuit board 10B may include a receiver 12c and a demodulator 12d.

A serial signal (baseband signal) from the serializer 11a is input to the modulator 12a. The modulator 12a modulates the input serial signal and then outputs the signal. The modulation method is, for example, amplitude modulation. The modulation method may be frequency modulation or phase modulation. In addition, the modulator 12a may also perform multi-level modulation. The transmitting part 12b includes a voltage controlled oscillator (VCO), a mixer, a power amplifier, and the like. Furthermore, the transmitting part 12b multiplies the modulated signal and the output signal of the voltage controlled oscillator using a mixer, generates (up-converts) a high frequency RF signal (RF signal with a millimeter wave frequency), and outputs this to the antenna 13A as an RF signal.

In the first circuit board 10A, the antenna 13A and RF circuit 12A are connected via an RF signal transmission line 16A. In a similar manner, in the second circuit board 10B, the antenna 13B and the RF circuit 12B are connected via an RF signal transmission line 16B. The RF signal transmission lines 16A and 16B are single-ended transmission lines. The RF signal transmission lines 16A and 16B may be a microstrip line or a strip line.

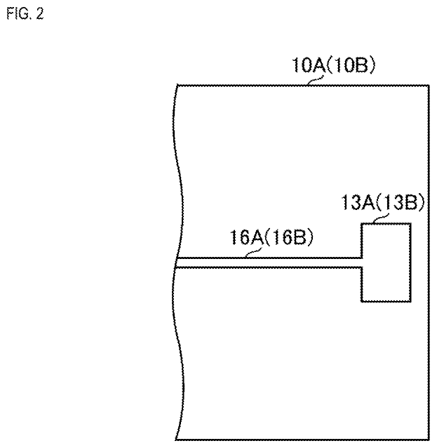

FIG. 2 is a plan view of the circuit boards 10A and 10B showing antennas 13A and 13B. As indicated in this FIG. 2, the antenna 13A may be a pattern antenna formed on the first circuit board 10A. The antenna 13B may be a pattern antenna formed on the second circuit board 10B. The antennas 13A and 13B convert the RF signals (electrical signals) input from the RF circuits 12A and 12B to radio waves and radiate them toward the dielectric waveguide 21. In addition, the antennas 13A and 13B convert the radio waves received from the dielectric waveguide 21 into RF signals (electrical signals) and output them to the receiver 12c. If the connectors 14A and 14B, described below, are interconnected with the connectors 22A and 22B of the dielectric waveguide 21, the end surface of the dielectric waveguide 12 [sic.] is provided facing the antennas 13A and 13B. Note that the antennas 13A and 13B are not necessarily pattern antennas formed on the circuit boards 10A and 10B, but may be a monopole antenna, dipole antenna, or the like connected via wiring to the RF signal transmission lines 16A and 16B formed on the circuit boards 10A and 10B.

The receiver 12c of the second circuit board 10B (see FIG. 1) includes an amplifier, a bandpass filter, a mixer, and a voltage controlled oscillator (VCO), amplifies the RF signal input from the antenna 13B, and multiplies the output signal of the voltage controlled oscillator and the RF signal to lower (down convert) the frequency of the high frequency RF signal. Furthermore, the receiving part 12c then outputs the RF signal with lowered frequency to the demodulator 12d. The demodulator 12d demodulates the RF signal and outputs a serial signal (baseband signal). The modulation method is, for example, amplitude modulation, but may also be frequency modulation or phase modulation.

Connectors 14A and 14B (see FIG. 1) are mounted respectively on the two circuit boards 10A and 10B. For example, the connectors 14A and 14B may be soldered on the surface of the circuit boards 10A and 10B. The connectors 14A and 14B are respectively connected to and retained by connectors 22A and 22B provided on the end parts of the dielectric waveguide 21. In other words, the connector 22A provided at a first end part of the dielectric waveguide 21 and the connector 14A of the first circuit board 10A are connected together, and thereby isolation thereof is controlled. The connector 14A of the first circuit board 10A and the connector 22A of the dielectric waveguide 21 may be detachable from each other. In a similar manner, the connector 22B provided on a second end part of the dielectric waveguide 21 and the connector 14B of the second circuit board 10B are connected together, and thereby isolation thereof is controlled. The connector 14B of the second circuit board 10B and the connector 22B of the dielectric waveguide 21 may be detachable from each other.

Positioning of the antennas 13A and 13B and dielectric waveguide 21 end surfaces (radio wave incident/radiating surface) may be set when the connectors 14A and 14B and the connectors 22A and 22B are connected together. In other words, the relative position of the antenna 13A and the dielectric waveguide 21 end surface may be controlled in a direction parallel to the surface of the first circuit board 10A. Similarly, the relative position of the antenna 13B and the dielectric waveguide 21 end surface may be controlled in a direction parallel to the surface of the second circuit board 10B. In addition, the relative position of the antenna 13A and the dielectric waveguide 21 end surface may be controlled in a direction perpendicular to the first circuit board 10A and the relative position of the antenna 13B and the dielectric waveguide 21 end surface may be controlled in a direction perpendicular to the second circuit board 10B.

The dielectric waveguide 21 may be formed of, for example, liquid crystal polymer resin (LCP resin), polyphenylene sulfide resin (PPS resin), polyamide, polybutylene terephthalate, or the like resin. The dielectric waveguide 21 may be flexible. In this case, a degree of freedom in the positions of the two circuit boards 10A and 10B can be ensured. In addition, by using a dielectric body as the waveguide 21, manufacturing cost can be reduced compared to a metal waveguide. The thickness of the dielectric waveguide 21 is adapted to the millimeter wave frequency that is transmitted and received between the antennas 13A and 13B. The cross section of the dielectric waveguide 21 is, for example, rectangular. The shape of the cross section and dimension of the cross section of the dielectric waveguide 21 is not in particular limited as long as they are compatible with transmission and receiving of radio waves between the antennas 13A and 13B.

The electronic device 100 may have a dielectric waveguide 21 and a shield (metal plate) surrounding the connectors 22A and 22B provided on the end part thereof. This shield suppresses external radiating of electromagnetic waves from the dielectric waveguide 21 and suppresses effects of external electromagnetic waves on signal transmission by means of the dielectric waveguide 21.

As described above, the electronic device 100 includes the SerDes 11A and 11B and transmits and receives serial signals between circuit boards 10A and 10B via the dielectric waveguide 21. Therefore, for example, the two circuit boards are connected using an FPC, and differing from electronic devices that transmit and receive parallel signals via FPC, the number of signal wires can be reduced. In addition, when attempting to transmit and receive high speed serial signals using wiring, a problem arises in that both increased signal wire distance or increased frequency leads to greater attenuation of the signal. With the electronic device 100, the signal is transmitted and received via the dielectric waveguide 21 between the circuit boards 10A and 10B and so attenuation of the signal along the transmission path can be suppressed. In addition, attenuation of the radio waves can be suppressed, as compared to the case of transmitting and receiving radio waves between at least two antennas 13A and 13B using the waveguide 21.

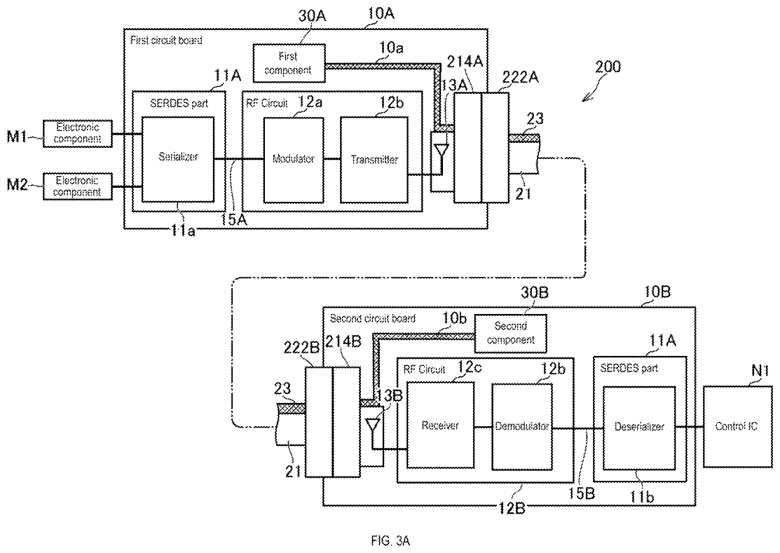

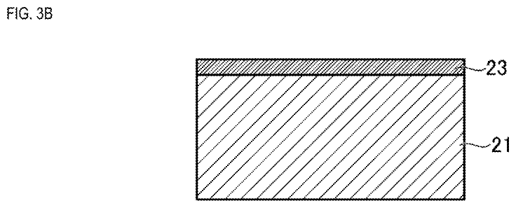

FIG. 3A is a block diagram depicting an electronic device 200 as a modified example of the electronic device 100. In this diagram, elements described with reference to FIG. 1 have the same symbols applied. Hereinafter, the description of the electronic device 200 will be provided, centered on the points of difference with the electronic device 100 depicted in FIG. 1. Matters not described with regard to the electronic device 200 may be the same as the electronic device 100 depicted in FIG. 1.

As depicted in FIG. 3A, the dielectric waveguide 21 may include a conductor line 23 on the outer surface thereof. The conductor line 23 is, for example, a thin film of metal. The conductor line 23 may be formed using printing, vapor deposition, or plating.

FIG. 3B is a cross section view depicting an example of the dielectric waveguide 21 and the conductor line 23. As depicted in FIG. 3B, the conductor line 23 may be formed on only a part of the outer surface of the waveguide 21. For example, in the case the dielectric waveguide 21 includes a rectangular cross section, the conductor line 23 may be formed only on a single surface thereof.

As depicted in FIG. 3A, a first component 30A may be provided on the first circuit board 10A and a second component 30B may be provided on the second circuit board 10B. The first component 30A and second component 30B may be mutually connected via an electrical wire 10a formed on the first circuit board 10A, the conductor line 23, and an electrical wire 10b formed on the second circuit board 10B. Components 30A and 30B transmit and receive signals at lower frequencies than the signals transmitted and received between the antennas 13A and 13B via the conductor line 23. The output signal of the first component 30A may be input to a control IC (N1) via the conductor line 23. In this case, the electronic device 200 may include the second component 30B. The first component 30A (or second component 30B) may supply direct current to the second component 30B (or first component 30A) via the conductor line 23. For example, the first component 30A may receive power from a battery (not depicted) built-in to the electronic device 100 and the electronic component (including the second component 30B) may be a power management IC that generates a power supply. The second component 30B may be a control IC (N1) including a CPU, a display, or various other components.

As depicted in FIG. 3A, the dielectric waveguide 21 includes connectors 222A and 222B at both ends thereof. Connectors 214A and 214B are respectively mounted on circuit boards 10A and 10B. When the connector 214A and the connector 222A are connected together, positioning of one end surface of the dielectric waveguide 21 and the antenna 13A is determined and the electrical wire 10a and conductor line 23 are electrically connected. When the connector 214B and the connector 222B are connected together, positioning of one end surface of the dielectric waveguide 21 and the antenna 13B is determined and the electrical wire 10b and conductor line 23 are electrically connected.

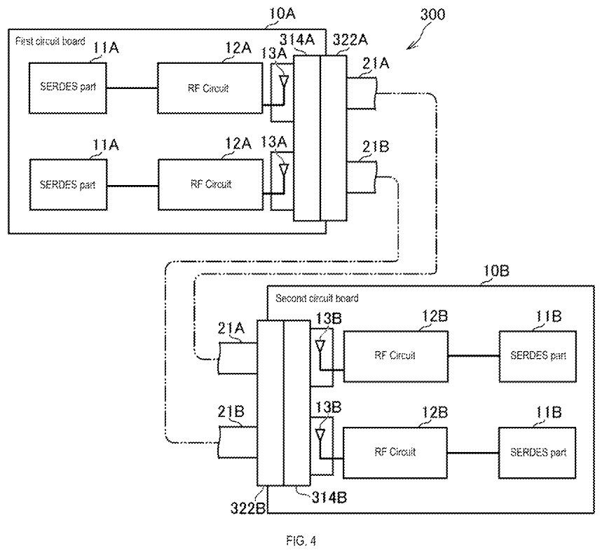

FIG. 4 is a block diagram depicting an electronic device 300 as a modified example of the electronic device 100. In this diagram, elements described with reference to FIG. 1 have the same symbols applied. Hereinafter, the description of the electronic device 300 will be provided, centered on the points of difference with the electronic device 100 depicted in FIG. 1. Matters not described with regard to the electronic device 300 may be the same as the electronic device 100 depicted in FIG. 1.

The electronic device 300 includes a plurality of dielectric waveguides. In the example depicted in the figures, the electronic device 300 includes two dielectric waveguides 21A and 21B. The two dielectric waveguides 21A and 21B include a common connector 322A at one end part thereof and a common connector 322B at another end part. In other words, the connectors 322A and 322B retain the end parts of the two dielectric waveguides 21A and 21B. The number of dielectric waveguides included on the electronic device 300 is not limited to two and may be three or four.

The distance between the dielectric waveguides 21A and 21B is desirably set such that no crosstalk occurs. In this case, the electronic device 300 may include a holder that retains the two dielectric waveguides 21A and 21B midway while regulating the distance therebetween. This holder may be provided at a plurality of positions between both ends of the dielectric waveguides 21A and 21B.

As depicted in FIG. 4, the first circuit board 10A includes two antennas 13A and 13A and one connector 314A and the second circuit board 10B also includes two antennas 13B and 13B and one connector 314B. When the connector 314A and the connector 322A of the dielectric waveguides 21A and 21B are connected, positioning is determined for the two antennas 13A and 13A mounted on the first circuit board 10A and for the end surface of the two dielectric waveguides 21A and 21B. Similarly, when the connector 314B and the connector 322B are connected, positioning is determined for the two antennas 13B and 13B mounted on the second circuit board 10B and for the end surface of the two dielectric waveguides 21A and 21B.

As depicted in FIG. 4, the first circuit board 10A includes two RF circuits 12A and 12A respectively connected to the two antennas 13A and 13A and two SerDes parts 11A and 11A respectively connected to the two RF circuits 12A and 12A. Similarly, the second circuit board 10B includes two RF circuits 12B and 12B respectively connected to the two antennas 13B and 13B and two SerDes parts 11B and 11B respectively connected to the two RF circuits 12B and 12B.

FIG. 5 is a block diagram depicting an electronic device 400 as a modified example of the electronic device 100. In this diagram, elements described with reference to FIG. 1 have the same symbols applied. Hereinafter, the description of the electronic device 400 will be provided, centered on the points of difference with the electronic device 100 depicted in FIG. 1. Matters not described with regard to the electronic device 400 may be the same as the electronic device 100 depicted in FIG. 1.

On the first circuit board 10A of FIG. 5, the SerDes part 11A includes a deserializer 11b in addition to the serializer 11a and the RF circuit 12A includes receiver 12c and demodulator 12d in addition to the modulator 12a and transmitter 12b. On the other hand, on the second circuit board 10B, the SerDes part 11B includes the serializer 11a in addition to the deserializer 11b and the RF circuit 12B includes the modulator 12a and transmitter 12b.

The output signals (digital signals) of the plurality of electronic components N3 and N4 are input to the serializer 11a of the second circuit board 10B. The serializer 11a may generate a serial signal including the output signals of a plurality of electronic components N3 and N4. A parallel signal may be input from one electronic component N3 (or N4) to the serializer 11a, and the serializer 11a may convert this parallel signal to a serial signal. The electronic components N3 and N4 may be an acceleration sensor, a temperature sensor for detecting battery (not depicted) temperature, a wireless communication module, a GNSS receiver, a touch sensor, an image sensor, or the like. The deserializer 11b of the first circuit board 10A receives a serial signal output from the serializer 11a via the RF circuit 12B (modulator 12a and transmitter 12b), dielectric waveguide 21, and RF circuit 12A (receiver 12c and demodulator 12d). The serial signal is separated into the original plurality of output signals and output, and thus the serial signal is converted into the original parallel signals and output. In the first circuit board 10A, the electronic component M3 into which signals from the deserializer 11b are input may be a wireless communication module or a control IC.

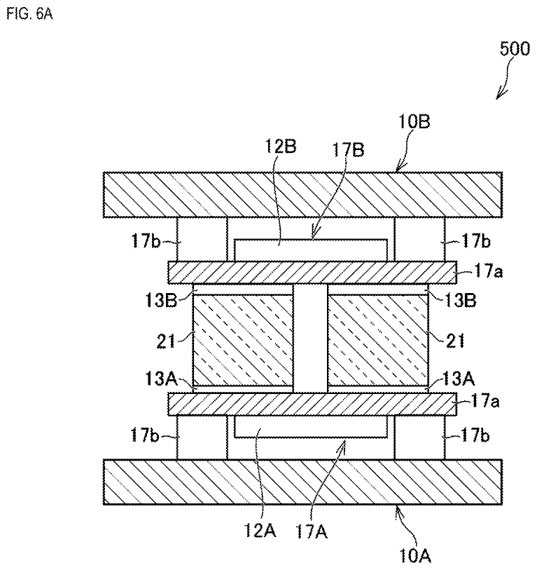

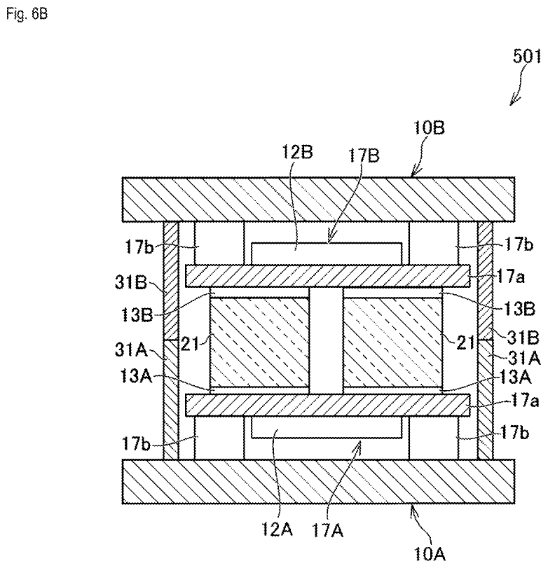

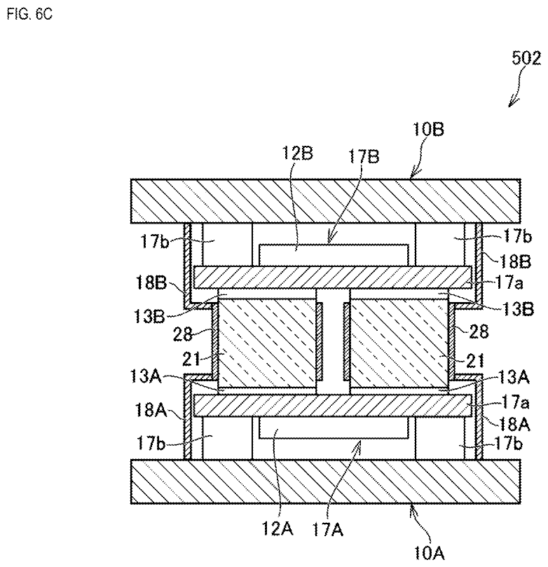

FIG. 6A is a cross section view schematically depicting an example of an arrangement of the circuit boards 10A and 10B on an electronic device 500. In this diagram, elements described with reference to FIG. 1 have the same symbols applied. Hereinafter, matters not described with regards to the electronic device 500 may be the same as the electronic device 100 depicted in FIG. 1. The arrangement of the circuit boards 10A and 10B, the dielectric waveguide 21, and the like depicted in FIG. 6A may apply the arrangement of the circuit boards 10A and 10B and the like of electronic devices 100, 200, 300, and 400 described above.

The first circuit board 10A and the second circuit board 10B may be arranged facing each other, as depicted in FIG. 6A. An RF module 17A having a board 17a is provided on the first circuit board 10A and an RF module 17B having a board 17a is provided on the second circuit board 10B. Furthermore, an RF circuit 12A is mounted on one surface of the board 17a of the RF module 17A and an antenna 13A is formed on another surface of the board 17a. In addition, an RF circuit 12B is mounted on one surface of the board 17a of the RF module 17B and an antenna 13B is formed on another surface of the board 17a. Therefore, the RF modules 17A and 17B are arranged overlapping with the circuit boards 10A and 10B in plan view and positioned between the circuit boards 10A and 10B. Therefore, the size of the circuit boards 10A and 10B can be reduced. In addition, modularization of the antennas 13A and 13B and RF circuits 12A and 12B simplifies assembly of the electronic device 500. A SerDes part 11A described above is mounted on the first circuit board 10A and a SerDes part 11B described above is mounted on the second circuit board 10B. In addition, electronic components M1 and M2 that are sensors, wireless communication modules, or the like may be mounted on the first circuit board 10A, and the control IC (N1) may still be mounted on the circuit board 10B.

The antenna 13A and RF circuit 12A may be arranged to at least partially overlap in plan view of the board 17a. Similarly, the antenna 13B and RF circuit 12B may be arranged to at least partially overlap in plan view of the board 17a. In this manner, the size of the RF modules 17A and 17B can be reduced.

The board 17a may be electrically connected to a conductor pad (not depicted) formed on the circuit boards 10A and 10B via a mounting portion 17b and may be mechanically secured to the circuit boards 10A and 10B via a mounting part 17b. For example, the board 17a may be soldered to the circuit boards 10A and 10B. In this case, the mounting part 17b may be solder balls. In contrast, the mounting part 17b may be a socket mounted on the circuit boards 10A and 10B that retains the board 17a and electrically connects the board 17a and the circuit boards 10A and 10B.

The antenna 13A provided on the first circuit board 10A side and the antenna 13B provided on the second circuit board 10B face each other in the thickness direction of the circuit boards 10A and 10B. Furthermore, the dielectric waveguide 21 is arranged between the antennas 13A and 13B along the thickness direction of the circuit boards 10A and 10B. The end surface of the dielectric waveguide 21 may be connected to the boards 17a and 17b via the connectors 14A and 14B (see FIG. 1).

As depicted in FIG. 6A, with the electronic device 500, two antennas 13A are formed on the board 17a provided on the first circuit board 10A. Similarly, two antennas 13B are formed on the substrate 17A provided on the second circuit board 10B. The two antennas 13A face the two antennas 13B. Furthermore, two dielectric waveguides 21 are provided respectively on the two groups of antennas 13A and 13B. In this case, one of the dielectric waveguides 21 may be used for transmitting signals from the first circuit board 10A to the second circuit board 10B. Furthermore, another of the dielectric waveguides 21 may be used for transmitting signals from the second circuit board 10B to the first circuit board 10A. In this case, the SerDes parts 11A and 11B of the first circuit boards 10A and 10B respectively may include the serializer 11a and the deserializer 11b, as depicted in FIG. 5. In addition, the RF circuits 12A and 12B may respectively include the modulator 12a, transmitter 12b, receiver 12c, and demodulator 12d.

FIG. 6B is a cross section view schematically depicting an electronic device 501 as another example of an arrangement of the circuit boards 10A and 10B and the like. As depicted in this figure, the electronic device 501 may include the RF modules 17A and 17B, the dielectric waveguide 21, and shields 31A and 31B surrounding the mounting part 17b. The shields 31A and 31B suppress the effects of unwanted radiation in the electronic device 501 during signal transmission via the dielectric waveguide 21, in other words, suppress the effects of radio waves transmitted via the dielectric waveguide 21 on other transmitted signals in the electronic device 501. The shield 31A secured to the first circuit board 10A and the shield 31B secured to the second circuit board 10B are connected. The shields 31A and 31B may be formed of, for example, metal plates.

FIG. 6C is a cross section view schematically depicting an electronic device 502 as another example of an arrangement of the circuit boards 10A and 10B and the like. As depicted in this figure, a shield 28 may be formed on the outer surface of each dielectric waveguide 21. The shield 28 may be formed on the entire outer surface of dielectric waveguide 21 except for the end surface. In addition, shields 18A and 18B stowing respectively RF modules 17A and 17B may be provided on the circuit boards 10A and 10B. Furthermore, the shields 18A and 18B may be electrically connected to the shield 28 formed on the outer surface of the dielectric waveguide 21.

As described above, the electronic devices 100, 200, 300, and 400 include an antenna 13A formed on the first circuit board 10A, an antenna 13B formed on the second circuit board 10B, and a dielectric waveguide 21 arranged between the antenna 13A and the antenna 13B. The first circuit board 10A includes a serializer 11a of SerDes part 11A and the RF circuit 12A that modulates the serial signal output from the serializer 11a and outputs the signal as an RF signal to the antenna 13A. The second circuit board 10B includes the RF circuit 12B that demodulates an RF signal input from the antenna 13B and outputs the signal as a serial signal and the deserializer 11b of the SerDes part 11B that converts the serial signal output from the RF circuit 12B to a parallel signal and outputs the signal. With these electronic devices 100, 200, 300, 400, signals are transmitted and received between the circuit boards 10A and 10B via the dielectric waveguide 21. Therefore, for example, the two circuit boards are connected using an FPC, and differing from electronic devices that transmit and receive parallel signals via FPC, the number of signal wires can be suppressed. In addition, signal attenuation can also be suppressed, unlike an electronic device that transmits and receives high frequency waves via wiring patterns formed on the circuit board.

In addition, the connector 14A is mounted on the first circuit board 10A and the connector 14B is mounted on the second circuit board 10B. The connector 22A for connecting to the connector 14A is attached to one end part of the dielectric waveguide 21 and the connector 22B for connecting to the connector 14B is attached to the other end part of the dielectric waveguide 21. Therefore, the relative position of the end part of the dielectric waveguide 21 and the antennas 13A and 13B can be controlled.

With the electronic device 200 (see FIG. 4A), the conductor line 23 is formed on the outer surface of the dielectric waveguide 21. The first component 30A is mounted on the first circuit board 10A and the first component 30B [sic] is mounted on the second circuit board 10B. Furthermore, the first component 30A (or second component 30B) outputs a low frequency signal or direct current to the second component 30B (or first component 30A) via the conductor line 23. Therefore, an increase in the number of components can be suppressed and low frequency signals or direct current can be sent and received between the components 30A and 30B.

With the electronic device 300 (see FIG. 5), two antennas 13A and 13A are formed on the first circuit board 10A and two antennas 13B and 13B are formed on the second circuit board 10B. The electronic device 300 has two dielectric waveguides 21A and 21B for transmitting high frequencies between the two antennas 13A and 13A and the two antennas 13B and 13B. Thus, more serial signals can be transmitted and received between the two circuit boards 10A and 10B at higher speeds. In addition, setting appropriate spacing between the dielectric waveguides 21A and 21B suppresses signal interference.

With the electronic devices 500, 501, and 502, the RF module 17A having the RF circuit 12A and the antenna 13A mounted therein is attached to the first circuit board 10A and the RF module 17B having the RF circuit 12B and the antenna 13B mounted therein is attached to the second circuit board 10B. Therefore, modularization of the RF circuit 12A and the antenna 13A as well as modularization of the RF circuit 12B and the antenna 13B simplifies assembly of the electronic device.

With the electronic devices 500, 501, and 502, the first circuit board 10A and second circuit board 10B are arranged facing each other in the vertical direction. The RF modules 17A and 17B are arranged such that the antennas 13A and 13B face each other in the vertical direction and the dielectric waveguide 21 is provided between the antennas 13A and 13B along the vertical direction.

1. A transmission system, comprising:
a first circuit board provided with a first antenna;
a second circuit board provided with a second antenna;
a first dielectric waveguide arranged between the first antenna and the second antenna, wherein
the first circuit board is provided with a serializer and a first RF circuit that modulates a serial signal output from the serializer and outputs the signal as an RF signal to the first antenna, and
the second circuit board is provided with a second RF circuit that demodulates an RF signal input from the second antenna and outputs the signal as a serial signal, and a deserializer that converts the serial signal output from the second RF circuit and outputs the signal as a parallel signal.

2. The transmission system according to claim 1, wherein
a first connector is mounted on the first circuit board,
a second connector is mounted on the second circuit board, and
the first dielectric waveguide includes a first end part provided with a connector for connecting to the first connector and a second end part provided with a connector for connecting to the second connector.

3. The transmission system according to claim 1, further comprising:
a conductor line formed on the outer surface of the first dielectric waveguide;
a first component; and
a second component, wherein
one component of the first component and the second component outputs a signal or direct current via the conductor line to another component of the first component or the second component.

4. The transmission system according to claim 1, further comprising:
a third antenna formed on the first circuit board;
a fourth antenna formed on the second circuit board; and
a second dielectric waveguide arranged between the third antenna and the fourth antenna.

5. The transmission system according to claim 1, wherein
a first RF module having the first RF circuit and the first antenna mounted therein is attached to the first circuit board, and
a second RF module having the second RF circuit and the second antenna mounted therein is attached to the second circuit board.

6. The transmission system according to claim 5, wherein
the first circuit board and the second circuit board are arranged facing each other in a first direction,
the first RF module and the second RF module are arranged so that the first antenna and the second antenna face each other, and
the dielectric waveguide is arranged along the first direction between the first antenna and the second antenna.
